(19) United States
(12) Patent Application Publication
(10) Pub. No.: US 2017/0110511 A1
(43) Pub. Date: Apr. 20, 2017

(54) SEMICONDUCTOR INTEGRATED CIRCUIT DEVICE CAPABLE OF REDUCING A LEAKAGE CURRENT

(71) Applicant: SK hynix Inc., Gyeonggi-do (KR)

(72) Inventor: Dong Yean OH, Gyeonggi-do (KR)

(21) Appl. No.: 15/050,872

(22) Filed: Feb. 23, 2016

(30) Foreign Application Priority Data
Oct. 19, 2015 (KR) 10-2015-0145315

(51) Int. Cl. H01L 27/24; H01L 29/267; H01L 29/06; H01L 29/49; H01L 29/78; H01L 29/423; H01L 27/22; H01L 29/165; H01L 29/08

(52) U.S. Cl. CPC H01L 27/2436; H01L 29/165; H01L 29/267; H01L 29/0673; H01L 29/0847; H01L 29/7833; H01L 29/42392; H01L 27/228; H01L 29/4983

(57) ABSTRACT

A semiconductor integrated circuit device may include a semiconductor substrate, a source pattern, a drain pattern, a nano wire pattern and a gate. The source pattern may be formed on an upper surface of the semiconductor substrate. The drain pattern may be formed on the upper surface of the semiconductor substrate. The drain pattern may be spaced apart from the source pattern. The nano wire pattern may be arranged between the source pattern and the drain pattern. The gate may be configured to surround the nano wire pattern. The nano wire pattern may include an inner wire and an outer wire. The inner wire may include a first semiconductor material. The outer wire may include a second semiconductor material having a band gap greater than a band gap of the first semiconductor material. The outer inner may be formed on an outer surface of the inner wire.

### CROSS-REFERENCES TO RELATED APPLICATION

The present application claims priority under 35 U.S.C. §119(a) to Korean application number 10-2015-0145315, filed on Oct. 19, 2015, which is herein incorporated by reference in its entirety.

### BACKGROUND

1. Technical Field

Various embodiments generally relate to a semiconductor integrated circuit device, more particularly, to a semiconductor integrated circuit device capable of reducing a leakage current.

2. Related Art

Currently, memory devices require access elements having a high integrated degree and high performance A typical one of the access elements may include a MOS transistor. The MOS transistor may have various shapes in order to provide the MOS transistor with the high integration degree and the high performance.

According to related arts, by forming the MOS transistor having the various shapes in a small area, a low leakage current characteristic may be ensured.

### SUMMARY

According to example embodiments, there may be provided a semiconductor integrated circuit device. The semiconductor integrated circuit device may include a semiconductor substrate, a source pattern, a drain pattern, a nano wire pattern and a gate. The source pattern may be formed on an upper surface of the semiconductor substrate. The drain pattern may be formed on the upper surface of the semiconductor substrate. The drain pattern may be spaced apart from the source pattern. The nano wire pattern may be arranged between the source pattern and the drain pattern. The gate may surround the nano wire pattern. The nano wire pattern may include an inner wire and an outer wire. The inner wire may include a first semiconductor material. The outer wire may include a second semiconductor material having a band gap greater than a band gap of the first semiconductor material. The outer inner may be formed on an outer surface of the inner wire.

According to example embodiments, there may be provided a semiconductor integrated circuit device. The semiconductor integrated circuit device may include a nano wire, a drain pattern, a source pattern, a gate and a gate insulating layer. The nano wire may be extended in a direction substantially parallel to an upper surface of a semiconductor substrate. The drain pattern may be formed on the upper surface of the semiconductor substrate to fix one end of the nano wire. The drain pattern may be heavily doped with impurities. The source pattern may be formed on the upper surface of the semiconductor substrate to fix the other end of the nano wire. The source pattern may be heavily doped with the impurities. The gate may surround the nano wire. The gate insulating layer may be formed between the nano wire and the gate. A portion of the gate adjacent to the drain pattern may have a work function lower than a work function of a portion of the gate configured to surround a central portion of the nano wire.

### BRIEF DESCRIPTION OF THE DRAWINGS

Exemplary embodiments will be described with reference to the to accompanying drawings. FIGS. 1 to 12 illustrate non-limiting examples and embodiments.

FIG. 1 is a perspective view illustrating an exemplary semiconductor integrated circuit device.

FIG. 2 illustrates a cross-sectional view taken along a line II-II′ in FIG. 1.

FIG. 3 is a diagram illustrating an energy band an exemplary semiconductor integrated circuit device.

FIG. 4 is a perspective view illustrating an exemplary semiconductor integrated circuit device.

FIG. 5 illustrates a cross-sectional view taken along a line V-V′ in FIG. 4.

FIG. 6 illustrates a cross-sectional view taken along a line VI-VI′ in FIG. 4.

FIG. 7 is a diagram illustrating an energy band of an exemplary semiconductor integrated circuit device.

FIG. 8 is a perspective view illustrating an exemplary semiconductor integrated circuit device.

FIG. 9 is a perspective view illustrating an exemplary semiconductor integrated circuit device.

FIG. 10 is a block diagram illustrating an exemplary microprocessor.

FIG. 11 is a block diagram illustrating an exemplary processor.

FIG. 12 is a block diagram illustrating an exemplary system.

### DETAILED DESCRIPTION

Various exemplary embodiments will be described more fully hereinafter with reference to the accompanying drawings, in which some embodiments are shown. The present invention may, however, be embodied in many different forms and should not be construed as limited to the embodiments set forth herein. In the drawings, the sizes and relative sizes of layers and regions may be exaggerated for clarity.

It will be understood that when an element or layer is referred to as being “on,” “connected to or “coupled to” another element or layer, it can be directly on, connected or coupled to the other element or layer, or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that terms such as first, second, and third may be used herein to describe various elements, components, regions, layers and/or sections, and these elements, components, regions, layers and/or sections should not be limited by these terms. These terms are only used to distinguish one element, component, region, layer or section from another element, component, region, layer or section.

Spatially relative terms, such as “beneath,” “below,” “lower,” “above,” “upper” and the like may be used herein to describe the relationship between element(s) or feature(s) as illustrated in the figures. It will be understood that the spatially relative terms provided herein is exemplary and may have different orientations from the orientation depicted herein. For example, in a situation where the device shown in the given figures is turned over, elements described as “below” or “beneath” other elements or features would then be placed “over” or “above” the other elements or features. Thus, the exemplary term “below” may indicate either“'above” or “below.’ The terminology used herein is for the purpose of describing particular embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Exemplary embodiments are described herein with reference to cross-sectional illustrations, Variations in shapes, in manufacturing techniques, and/or in tolerances are expected. Thus, embodiments should not be construed as limited to the particular shapes of regions illustrated herein. For example, even though illustrated as a rectangle, an implanted region may be rounded or curved. In addition, implant concentration may be different depending on locations.

Unless otherwise defined, all terms including technical and scientific terms, used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art.

Hereinafter, exemplary embodiments will be described in detail with reference to the accompanying drawings.

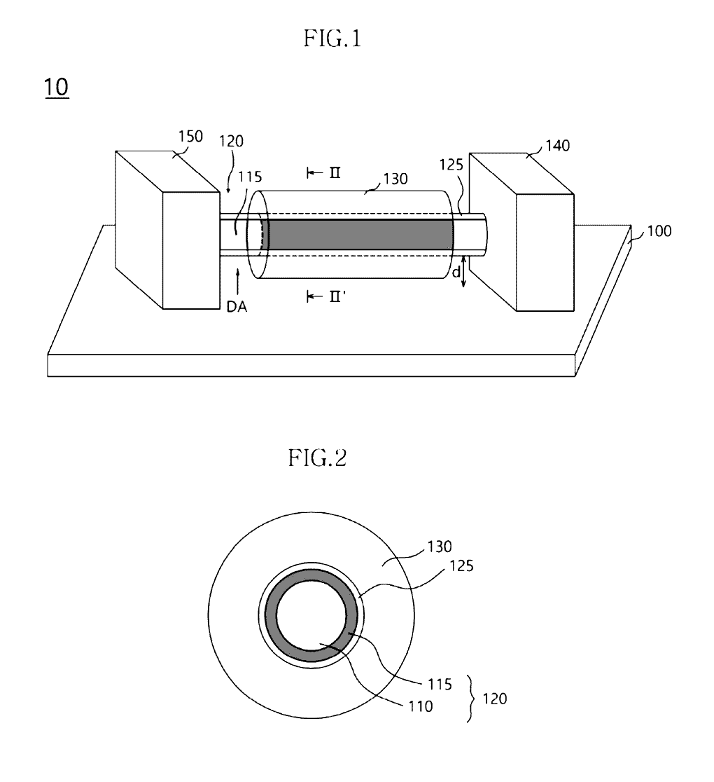

FIG. 1 is a perspective view illustrating a semiconductor integrated circuit device in accordance with example embodiments and FIG. 2 is a cross-sectional view taken along a line II-II′ in FIG. 1.

Referring to FIGS. 1 and 2 an exemplary transistor 10 may include a nano wire pattern 120 extended in a direction substantially parallel to an upper surface of a semiconductor substrate 100. The nano wire pattern 120 may include a semiconductor material. The nano wire pattern 120 may be floated from the upper surface of the semiconductor substrate 100 by a distance d.

The nano wire pattern 120 may be formed between a source pattern 140 and a drain pattern 150. Particularly, the source pattern 140 may be contacted with one end of the nano wire pattern 120. The drain pattern 150 may be contacted with the other end of the nano wire 120. The source pattern 140 and the drain pattern 150 may be formed on the upper surface of the semiconductor substrate 100. The source pattern 140 and the drain pattern 150 may include a semiconductor material substantially the same as a semiconductor material of the semiconductor substrate 100. The source pattern 140 and the drain pattern 150 may correspond to a heavily doped region to be used for electrodes of a MOS transistor. Portions of the nano wire pattern 130 adjacent to the source pattern 140 and the drain pattern 150 may correspond to a heavily doped region by the impurity implantation process. Further, a lightly doped region (LDD) may be formed in a portion DA of the nano wire pattern 120 between the drain pattern 150 and, a gate 130 to decrease an electric field concentration

The gate 130 may be formed on an outer surface of the nano wire pattern 120. Thus the gate 130 may surround the nano wire pattern 120. The gate 130 may include a conductive material. For example, the gate 130 may include a conductive layer such as a doped polysilicon layer, a metal layer, etc. A driving voltage greater than a threshold voltage may be applied to the gate 130 to form a channel. A gate insulating layer 125 may be formed between the nano wire pattern 120 and the gate 130.

When the nano wire 120, including the semiconductor material, is doped with an impurity, a Fermi level of the nano wire pattern 120 may be increased due to the impurity. Thus, the doped semiconductor material, for example, an impurity doped silicon, may have a work function lower than a work function of intrinsic silicon without an impurity.

When a power voltage V may be applied to the drain pattern 150 and a voltage may be applied to the gate 130 to operate the MOS transistor, a high electric field may be concentrated on a portion of the gate 130 along an edge portion of the gate 130 adjacent to the drain pattern 150. Since the gate insulating layer 125 is thin film, the electric field between the gate 130 and the drain pattern 150 may be more concentrated to generate a gate induced drain leakage (GIDL).

In order to prevent the generation of the GIDL, the nano wire pattern 120 may include an inner wire 110 and an outer wire 115. The inner wire 110 may include a first semiconductor material. The outer wire 115 may include a second semiconductor material having a band gap greater than a band gap of the first semiconductor material. The outer wire 115 may surround the inner wire 110. For example, if the first semiconductor material may include silicon, then the second semiconductor material may include at least one of Ge, SiGe GaAs, or SiC, etc. Further, the second semiconductor material may have a thickness of about 5% to about 50% of a radius of the first semiconductor material to prevent decreasing of the channel mobility.

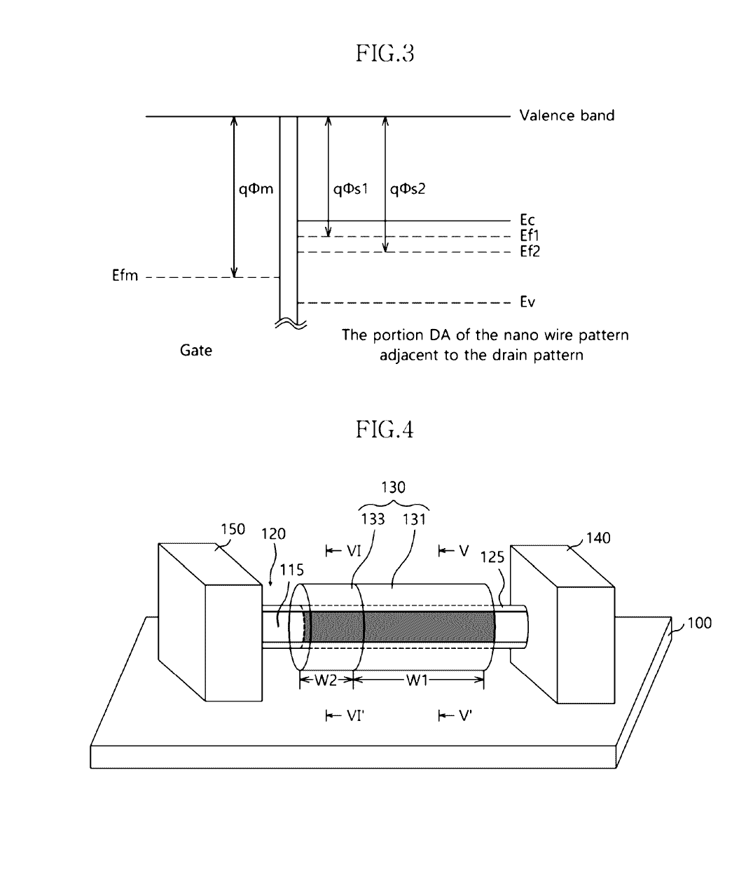

The outer wire 115, having the band gap greater than the band gap of the inner wire 110, may reduce an electric field concentration caused by a short channel and also increase a work function of the nano wire pattern 120. Thus, a difference between a work function of a portion DA of the nano wire pattern 120 adjacent to the gate 130 and the drain pattern 150 and a work function of the gate 130 may be decreased to reduce the leakage current. FIG. 3 is a diagram illustrating an energy band of an exemplary semiconductor integrated circuit device.

Referring to FIG. 3, the nano wire type transistor 10 may include an NMOS transistor. The inner wire 110 of the nano wire to pattern 120 may include silicon. The outer wire 115 of the nano wire pattern 120 may include silicon germanium. The portion DA of the nano wire pattern 120 adjacent to the drain pattern 150 can be doped with an impurity may have a Fermi level Ef1 substantially similar to a conductive band Ec of the silicon.

A constant voltage difference may be generated between a work function qΦm of about 4.0 eV to about 5.0 eV of the gate 130 and a work function qΦs1 of the portion DA in the nano wire pattern 120. Because the portion DA of the nano wire pattern 120 may correspond to the work function of the silicon doped with an N+ type impurity, the leakage current may be generated due to the difference between the work function of the gate 130 and the work function of the nano wire pattern 120.

In an embodiment, if the outer wire 115 may include the second semiconductor material having the band gap greater than the band gap of the inner wire 110, a Fermi level Ef2 of the portion DA in the nano wire pattern 120 may be decreased. As a result, the work function qΦs2 of the nano wire pattern 120 may be increased to reduce the difference between the work function of the nano wire pattern 120 and the work function qΦs of the gate 130, thereby reducing the GIDL. In FIG. 3, a reference numeral Efm refers to a Fermi level of the gate 130, and a reference numeral Ev refers to a valence band of the drain pattern 150, i.e., the silicon.

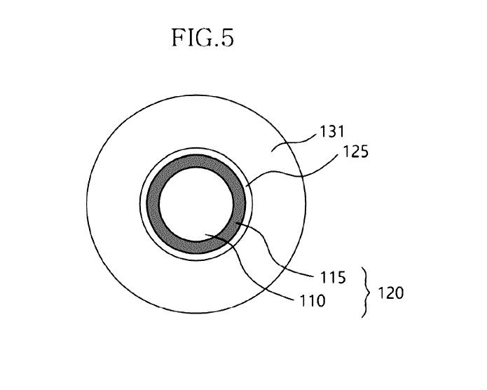

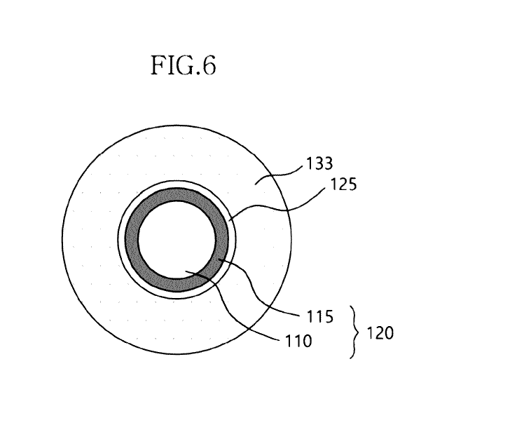

FIG. 4 is a perspective view illustrating an exemplary semiconductor integrated circuit device. FIG. 5 is a cross-sectional view to taken along a line V-V′ in FIG. 4, and FIG. 6 is a cross-sectional view taken along a line VI-VI′ in FIG. 4.

Referring to FIGS. 4 to 6, a gate 130 may include a first gate region 131 and a second gate region 133. The first gate region 131 may surround a central portion of the nano wire pattern 120 corresponding to a channel region. The second gate region 133 may be formed between the first gate 131 and the drain pattern 150. The first gate region 131 may have a width W1 wider than a width W2 of the second gate region 133.

The first gate region 131 may include a material having a first work function. The second gate region 133 may include a material having a second work function lower than the first work function.

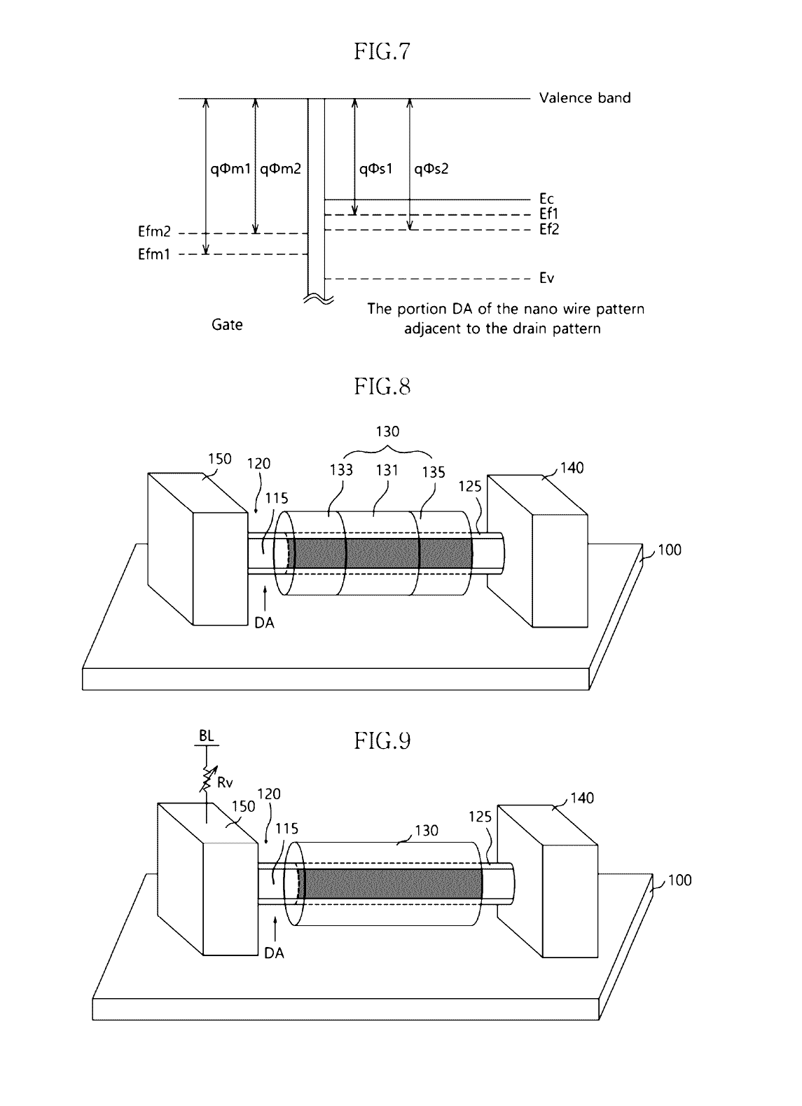

FIG. 7 is a diagram illustrating an energy band of exemplary semiconductor integrated circuit device.

Referring to FIG. 7, the material of the second gate region 133 formed at a region in which the electric field may be concentrated may have the second work function qΦm2 lower than the first work function qΦm1 of the material of the first gate region 131. Thus, the difference between the second work function qΦm2 of the second gate region 133 and the work function qΦs2 of the portion DA in the nano wire pattern 120 may be reduced, thereby decreasing the GIDL. In FIG. 7, a reference numeral qΦs1 refers to the work function of the first semiconductor material in the inner wire 110.

FIG. 8 is a perspective view illustrating a semiconductor integrated circuit device in accordance with example embodiments.

Referring to FIG. 8, the gate 130 may include a first gate region 131, a second gate region 133 and a third gate region 135. The first gate region 131 may be formed in a channel region. The second gate region 133 may be formed at one end of the first gate region 131 adjacent to the drain pattern 150. The third gate region 135 may be formed at the other end of the first gate region 131 adjacent to the source pattern 140. The first gate region 131 may include a gate conductive material having a first work function. The second gate region 133 and, the third gate region 135 may include a conductive material having a second work function lower than the first work function.

Alternatively, the third gate region 135 may include a conductive material having a third work function different from the first work function and the second work function. For example, the third work function may be lower than the first work function and higher than the second work function. Further, the third work function may be lower than the first work function and the second work function.

FIG. 9 is a perspective view illustrating an exemplary semiconductor integrated circuit device

Referring to FIG. 9, a variable resistance Rv may be electrically connected to the drain pattern 150. The variable resistance Rv may vary in accordance with kinds of variable resistive memory devices. For example, if the variable resistive memory device may include an ReRAM, then the variable resistance Rv may include a PCMO layer such as a chalcogenide layer. If the variable resistive memory device may include a MRAM, the variable resistance Rv may include a magnetic layer. If the variable resistive memory device includes a STTMRAM, then the variable resistance Rv may include a magnetization reversal layer.

In an example embodiment, the outer wire may include the material capable of reducing the electric field concentration in the MOS transistor having the nano wire type channel. Further, the material of the gate electrode may be changed. Thus, the difference between the work functions of the gate and the drain may be decreased to prevent the generation of the leakage current.

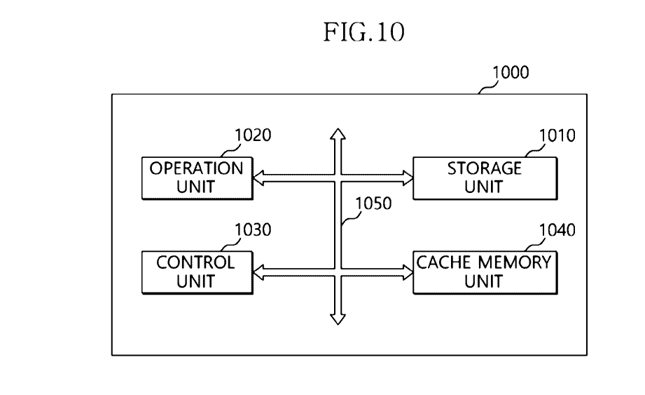

As illustrated in FIG. 10, a microprocessor 1000 using the exemplary semiconductor device may control and adjust a series of processes, which receive data from various external apparatuses, process the data, and transmit processing results to the external apparatuses. The microprocessor 1000 may include a storage unit 1010, an operation unit 1020, and a control unit 1030. The microprocessor 1000 may be a variety of processing apparatuses, such as a micro processing unit (MPU), a central processing unit (CPU), a graphic processing unit (GPU), a digital signal processor (DSP), or an application processor (AP).

The storage unit 1010 may be, a processor register or a register, and the storage unit may be a unit that stores data in the microprocessor 1000 and may include a data register, an address register, and a floating point register. The storage unit 1010 may include various registers other than the above-described registers. The storage unit 1010 may temporarily store data to be processed in the to operation unit 1020, resulting data that was processed in the operation unit 1020, and an address in which the data is stored.

The storage unit 1010 may include at least one of the exemplary semiconductor devices. The storage unit 1010 including the exemplary semiconductor device may use a tunneling transistor, in which a semiconductor material layer having a low band gap is inserted into or around a source, as a switching device.

The operation unit 1020 may perform an operation in the microprocessor 1000 and perform a variety of four fundamental arithmetic operations depending on a command of the control unit 1030. The operation unit 1020 may include one or more arithmetic and logic units (ALUs).

The control unit 1030 may receive a signal from the storage unit 1010, the operation unit 1020, or an external apparatus of the microprocessor 1000. The control unit 1030 may perform extraction or decoding of a command, or input or output control, and may execute a process in a program form,

An exemplary microprocessor 1000 may include a cache memory unit 1040 that may temporarily store data input from an external apparatus or data to be output to an external apparatus. The cache memory unit 1040 may exchange data with the storage unit 1010, the operation unit 1020, and the control unit 1030 through a bus 1050.

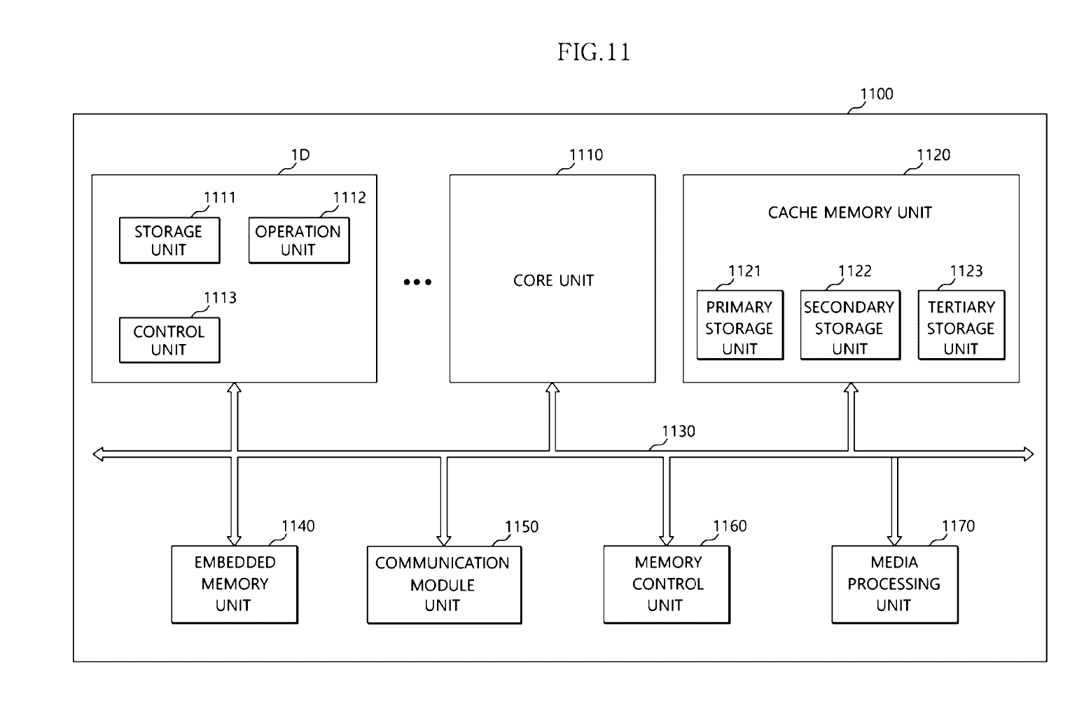

As illustrated in FIG. 11, a processor 1100 using the exemplary semiconductor device may implement various functions to improve performance and function. This is in addition to the functions of the microprocessor that may control and adjust a series of processes which receive data from various external apparatuses, process the data, and transmit processing results to the external apparatuses. The processor 1100 may include a core unit 1110, a cache memory unit 1120, and a bus interface 1130. The core unit 1110 may perform arithmetic and logic operations on data input from an external apparatus, and include a storage unit 1111, an operation unit 1112, and a control unit 1113. The processor 1100 may be a variety of system on chips (SoCs) such as a multi core processor (MCP) a graphics processing unit (GPU), or an application processor (AP).

The storage unit 1111 may be a processor register or a register, and the storage unit 1111 may be a unit that may store data in the processor 1100 and include a data register, an address register, and a floating point register. The storage unit 1111 may include various registers. The storage unit 1111 may temporarily store data to be operated on in the operation unit 1112, resulting data that was processed in the operation unit 1112, and an address in which the data to be operated on is stored.

The operation unit 1112 may be a unit that may perform an operation in the processor 1100 and perform a variety of four fundamental rules of an arithmetic operation or logic operations depending on a decoding result of a command in the control unit 1113. The operation unit 1112 may include one or more arithmetic and logic units (ALUs). The control unit 1113 receives a signal from the storage unit 1111, the operation unit 1112, or an external apparatus of the processor 1100, performs extraction or decoding of a command, or input or output control, and executes a process in a program form.

The cache memory unit 1120 may temporarily store data to improve the data processing rate of a low speed external apparatus. The cache memory unit 1120 may include a primary storage unit 1121, a secondary storage unit 1122, and a tertiary storage unit 1123. In general, the cache memory unit 1120 may include the primary and secondary storage units 1121 and 1122. When a high capacity storage unit is necessary, the cache memory unit 1120 may include the tertiary storage unit 1123. If necessary, the cache memory unit 1120 may include more storage units. That is, the number of storage units included in the cache memory unit 1120 may vary according to design.

Processing rates of the primary, secondary, and tertiary storage units 1121, 1122, and 1123 may be the same as or different from each other. When the processing rates of the storage units are different from each other, the processing rate of the primary storage unit may be set as the greatest.

One or more of the primary storage unit 1121, the secondary storage unit 1122, and the tertiary storage unit 1123 in the cache memory unit 1120 may include at least one exemplary semiconductor device. The cache memory unit 1120 may use a tunneling transistor, in which a semiconductor material layer having a low band gap is inserted into or around a source, such as a switching device.

Further, FIG. 11 illustrates that all the primary, secondary, tertiary storage units 1121, 1122, and 1123 are disposed in the cache memory unit 1120. However, some or all of the primary, secondary, tertiary storage units 1121, 1122, and 1123 in the cache memory unit 1120 may be disposed outside the core unit 1110, and may supplement the difference between the processing rates of the core unit 1110 and an external apparatus. Further, the primary storage unit 1121 of the cache memory unit 1120 may be located in the core unit 1110, and the secondary storage unit 1122 and the tertiary storage unit 1123 may be located outside the core unit 1110 to further supplement the processing rate.

The bus interface 1130 may couple the core unit 1110 and the cache memory unit 1120 to efficiently transmit data.

The exemplary processor 1100 may include a plurality of core units 1110, and the core units 1110 may share the cache memory unit 1120. The core units 1110 and the cache memory unit 1120 may be coupled through the bus interface 1130. The core units 1110 may have the same configuration as the above-described core unit 1110. When the core units 1110 are provided, the primary storage unit 1121 of the cache memory unit 1120 may be disposed in each of the core units 1110 corresponding to the number of core units 1110, and one secondary storage unit 1122 and one tertiary storage unit 1123 may be disposed outside the core units 1110 so that the core units share the secondary and tertiary storage units through the bus interface 1130. The processing rate of the primary storage unit 1121 may be greater than those of the secondary and tertiary storage units 1122 and 1123.

The processor 1100 may further include an embedded memory unit 1140 that may store data, a communication module unit 1150 that may transmit and receive data to and from an external apparatus in a wired or a wireless manner, a memory control unit 1160 that may drive an external storage device, and a media processing unit 1170 that may process data processed in the processor 1100 or data input from an external input device and may output a processing result to an external interface device. The processor may further include a plurality of modules in addition to the above-described components. The additional modules may transmit data to and receive data from the core unit 1110 and the cache memory unit 1120, and transmit and receive data therebetween through the bus interface 1130.

The embedded memory unit 1140 may include volatile memory as well as nonvolatile memory. The volatile memory may include a dynamic random access memory (DRAM), a mobile DRAM, a static RAM (SRAM), or the like. The nonvolatile memory may include a read only memory (ROM), a NOR flash memory, a NAND flash memory, a phase-change RAM (PCRAM), a resistive RAM (RRAM), a spin transfer torque RAM (STTRAM), a magnetic RAM (MRAM), or the like. The exemplary semiconductor device may also be applied to the embedded memory unit 1140.

The communication module unit 1150 may include a module coupled to a wired network and a module coupled to a wireless network. The wired network module may include a local area network (LAN), a universal serial bus (USB), Ethernet, power line communication (PLC), or the like. The wireless network module may include Infrared Data Association (IrDA), Code Division Multiple Access (CDMA), Time Division Multiple Access (TDMA), Frequency Division Multiple Access (FDMA), a wireless LAN, Zigbee, a Ubiquitous Sensor Network (USN) Bluetooth, Radio Frequency Identification (RFID), Long Term Evolution (LTE) Near Field Communication (NFC), Wireless Broadband Internet (Wibro), High Speed Downlink Packet Access (HSDPA), Wideband CDMA (WCDMA), Ultra WideBand (UWB), or the like.

The memory control unit 1160 may manage data transmitted between the processor 1100 and an external storage apparatus that may operate according to a different communication standard from the processor 1100. The memory control unit 1160 may include a variety of memory controllers or a controller that may control Integrated Device Electronics (IDE), Serial Advanced Technology Attachment (SATA), a Small Computer System Interface (SCSI), a Redundant Array of Independent Disks (RAID), a solid state disk (SSD), External SATA (eSATA), Personal Computer Memory Card International Association (PCMCIA), a USB, a secure digital (SD) card, a mini secure digital (mSD) card, a micro SD card, a secure digital high capacity (SDHC) card, a memory stick card, a smart media (SM) card, a multimedia card (MMC), an embedded MMC (eMMC), a compact flash (CF) card, or the like.

The media processing unit 1170 may process data processed in the processor 1100 or data input from an external input device, and may output a processing result to an external interface device so that the processing result may reproduce video, sound, etc. The media processing unit 1170 may include a GPU, a DSP, HD audio, a high definition multimedia interface (HDMI) controller, or the like.

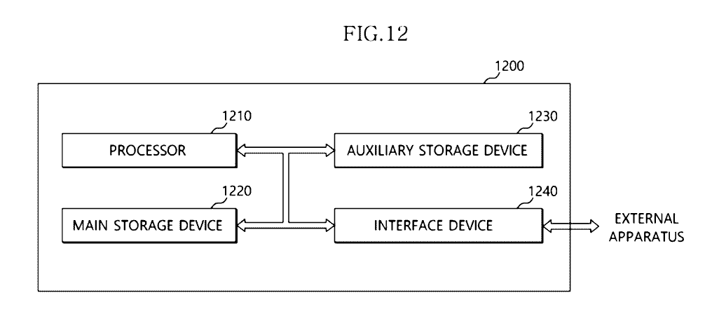

As illustrated in FIG. 12, a system 1200 using the exemplary semiconductor device may be a data processing apparatus. The system 1200 may perform input, processing, output, communication, storage, and the like to perform a series of operations on data, and include a processor 1210, a main storage device 1220, an auxiliary storage device 1230, and an interface device 1240. The system 1200 may include a variety of electronic systems that may operate using a processor, such as a computer, a server, a personal digital assistant (PDA), a portable computer, a web tablet, a wireless phone, a mobile phone, a smart phone, a digital music player, a portable multimedia player (PMP), a camera, a global positioning system (GPS), a video camera, a voice recorder, Telematics, an audio visual (AV) system, or a smart television.

The processor 1210 is a core configuration of the system that may decode an input command and processing such as an operation and comparison of data stored in the system, and may include a MPU, a CPU, a single/multi core processor, a GPU, an AP, a DSP, or the like.

The main storage device 1220 may receive a program or data from the auxiliary storage device 1230 and execute the program or the data. The main storage device 1220 retains the stored data even when power is interrupted, and may include at least one exemplary semiconductor device. The main storage device 1220 may use a tunneling transistor, in which a semiconductor material layer having a low band gap is inserted into or around a source, such as a switching device.

The main storage device 1220 may further include an SRAM or a DRAM of a volatile memory type in which all data is lost when power is off. Alternatively the main storage device 1220 may not include an exemplary semiconductor device, but may include an SRAM or a DRAM of a volatile memory type in which all data is lost when power is off.

The auxiliary storage device 1230 may store a program code or data The auxiliary storage device 1230 may have a lower data processing rate than the main storage device 1220 but may store large amounts of data and include at least one exemplary semiconductor device. The auxiliary storage unit 1230 may also use a tunneling transistor, in which a semiconductor material layer having a low band gap is inserted into or around a source, such as a switching device.

By using an exemplary semiconductor device, an area of the auxiliary storage device 1230 may be reduced, so that the overall size of the system 1200 is reduced and portability of the system 1200 is increased. Further,the auxiliary storage device 1230 may further include a data storage system (not shown), such as a magnetic tape or a magnetic disc, a laser disc using light, a magneto-optical disc using magnetism and light, an SSD, a USB memory, a SD card, a mSD card, a micro SD card, a SDHC card, a memory stick card, a SM card, a MMC, an eMMC, or a CF card. Alternatively, the auxiliary storage device 1230 may not include an exemplary semiconductor device, but may include a data storage system (not shown), such as a magnetic tape or a magnetic disc using a magnetism, a laser disc using light, a magneto-optical disc using magnetism and light, an SSD, a USB memory, a SD card, a mSD card, a micro SD card, a SDHC card, a memory stick card, a SM card a MMC, an eMMC, or a CF card.

The interface device 1240 may exchange a command and data of an external apparatus with the exemplary system and may be a keypad, a keyboard, a mouse, a speaker, a microphone, a display, a variety of Human Interface Devices (HIDs), or a communication device. The communication device may include multiple modules such as a module coupled to a wired network and a module coupled to a wireless network. The wired network module may include a LAN, a USB, Ethernet, PLC, or the like. The wireless network module may include IrDA, CDMA, TDMA, FDMA, a wireless LAN, Zigbee, a USN, Bluetooth, RFID, LTE, NFC, Wibro, HSDPA, WCDMA, UWB, or the like.

What is claimed is

1. A semiconductor integrated circuit device comprising:
a semiconductor substrate;
a source pattern formed on an upper surface of the semiconductor substrate;
a drain pattern formed on the upper surface of the semiconductor substrate, the drain pattern spaced apart from the source pattern;
a nano wire pattern arranged between the source pattern and the drain pattern, the nano wire pattern comprising:
an inner wire including a first semiconductor material having a first band gap;
an outer wire formed on an outer surface of the inner wire, the outer wire comprising a second semiconductor material having a second band gap greater than the first band gap; and
a gate surrounding the nano wire pattern.

2. The semiconductor integrated circuit device of claim 1, wherein the first semiconductor material comprises silicon, and the second material comprises at least one of Ge, SiGe, GaAs, or SC

3. The semiconductor integrated circuit device of claim 1, wherein the outer wire has a thickness of about 5% to about 50% of a radius of the inner wire.

4. The semiconductor integrated circuit device of claim 1, wherein the nano wire pattern further comprises a lightly doped drain (LDD) region in a portion of the nano wire pattern adjacent to the drain pattern, and the LDD region has a doping concentration lower than a doping concentration of the drain pattern.

5. The semiconductor integrated circuit device of claim 1, wherein the gate comprises:
a first gate surrounding a central portion of the nano wire pattern, the first gate having a first work function; and
a second gate arranged between one end of the first gate and the drain pattern the second gate having a second work function that is lower than the first work function,

6. The semiconductor integrated circuit device of claim 5, wherein the gate further comprises a third gate arranged between the other end of the first gate and the source pattern.

7. The semiconductor integrated circuit device of claim 6, wherein the third gate has a third work function that is lower than the first work function.

8. The semiconductor integrated circuit device of claim 7, wherein the second work function and the third work function are substantially the same.

9. The semiconductor integrated circuit device of claim 1, wherein the nano wire pattern is floated from the upper surface of the semiconductor substrate, and the nano wire pattern is fixed by the source pattern and the drain pattern.

10. The semiconductor integrated circuit device of claim 1, further comprising a gate insulating layer formed between the nano wire pattern and the gate.

11. The semiconductor integrated circuit device of claim 1, further comprising a variable resistance electrically connected to the drain pattern.

12. A semiconductor integrated circuit device comprising:
a nano wire extending in a direction substantially parallel to an upper surface of a semiconductor substrate;
a drain pattern formed on the upper surface of the semiconductor substrate to be contacted to one end of the nano wire, the drain pattern is including a first doped region;
a source pattern formed on the upper surface of the semiconductor substrate to be contacted to the other end of the nano wire, the source pattern including a second doped region;
a gate surrounding the nano wire; and
gate insulating layer formed between the nano wire and the gate,
wherein a portion of the gate adjacent to the drain pattern has a work function lower than a work function of a portion of the gate surrounding a central portion of the nano wire.

13. The semiconductor integrated circuit device of claim 12,
wherein the portion of the gate surrounding a central portion of the nano wire is a first gate region surrounding the central portion of the nano wire pattern and having a first work function, and
wherein the portion of the gate adjacent to the drain pattern is a second gate region arranged between one end of the first gate region and the drain pattern and having a second work function lower than the first work function.

14. The semiconductor integrated circuit device of claim 13 wherein the gate further comprises a third gate region arranged between the other end of the first gate and the source pattern.

15. The semiconductor integrated circuit device of claim 14, wherein the third gate has a third work function lower than the first work function.

16. The semiconductor integrated circuit device of claim 14, wherein the second gate region and the third gate region have substantially the same work function.

17. The semiconductor integrated circuit device of claim 12, wherein the nano wire is floated from the upper surface of the semiconductor substrate, the nano wire comprises an inner wire including a first semiconductor material, and an outer wire including a second semiconductor material having a band gap greater than a band gap of the first semiconductor material, and the outer wire is formed on an outer surface of the inner wire.

18. The semiconductor integrated circuit device of claim 17, wherein the first semiconductor material comprises silicon and the second material comprises at least one of Ge, SiGe, GaAs, or SiC.

19. The semiconductor integrated circuit device of claim 17, wherein the outer wire has a thickness of about 5% to about 50% of a radius of the inner wire.

20. The semiconductor integrated circuit device of claim 12, further comprising a variable resistance electrically connected to the drain pattern.
